(19) United States
(12) Patent Application Publication
(10) Pub. No.: US 2004/0135708 A1
(43) Pub. Date: Jul. 15, 2004

(54) Ordering weightless binary tuples according to hamming value

(76) Inventor: James Robert Armstrong, Lancashire (GB)

Correspondence Address: NIXON & VANDERHYE, PC, 1100 N GLEBE ROAD, 8TH FLOOR, ARLINGTON, VA, 22201-4714, US

(21) Appl. No.: 10/475,751

(22) PCT Filed: Feb. 21, 2003
(86) PCT No.: PCT/GB03/00780

(30) Foreign Application Priority Data
Feb. 25, 2002 (GB) 0204409.7

(51) Int. Cl. H03M 7/00

(52) U.S. Cl. 341/50

(57) ABSTRACT

An apparatus and a method are described for ordering a set of weightless binary tuples according to their Hamming value. The input tuples are applied to a multi-stage array of logic modules (22) each of which receives at least two of the input tuples, compares them, and carries out a selection step such that the at least two tuples applied to the input of each logic module are ordered by the logic module, successively to rearrange the input tuples in order of Hamming value.

This invention relates to apparatus and methods for ordering a set of weightless binary tuples according to their Hamming value (as herein defined).

There are many applications where it is required to order a set of weightless binary tuples (as herein defined) according to their Hamming value (for example to determine the weightless binary tuple of the set which has the median Hamming value (otherwise referred to as a “weightless median”) or either or both of the weightless binary tuples having the highest or lowest Hamming values (otherwise referred to as “weightless outliers”)). Indeed it may be useful also to identify other ranked members of the set other than the weightless median or the weightless outliers.

In one particular digital signal filtering operation, it is known to define a rolling window of defined extent which operates on a stream of digital samples, and to replace each value with a filtered value determined by a collective property of values in the window, typically a mean or median value, such as weightless median. There are other instances where the weightless outliers may be required, for example as a measure or metric of the homogeneity of the samples in the window.

Other instances where ordering of the Hamming values and/or determination of a weightless median and/or the weightless outliers may be required is in error detection and correction of digital code.

U.S. Pat. No. 6,330,702 discloses a Hamming value comparator which compares the Hamming value of two binary tuples and provides an output indicative of which has the higher Hamming value. There is mention also of comparing more than two tuples by suitable comparison and combination stages to compare successive pairs of the tuples to deduce their order, and then ordering: the tuples knowing the results of the comparison. However, although this earlier document suggests ordering the tuples after having made the comparisons, it does not disclose how to implement the ordering or how to retrieve the original bit pattern of the tuples. Particularly in environments where an asynchronous, memoryless, clockless implementation is desirable, there is a need for a method and apparatus which reorders an input set of binary tuples by successive manipulation of the tuples to provide an output of an ordered set of tuples in which the original bit pattern is preserved.

### DEFINITIONS

Weightless binary: This means that each active bit has unit weight—just “1” as opposed to “natural” weighted binary which has positional weightings of 1, 2, 4, 8 . . . .

Weightless binary tuple: This defines a collection of weightless bits in which the order is irrelevant. For example, [0 0 1 1], [1 1 0 0] and [1 0 1 0] each have the same significance.

Thermometer code (alternatively referred to as thermocode): This is a form of weightless binary in which the 1's and 0's within the tuple are grouped together. For example, [1 0 1 0 1] in thermocode is [1 1 1 0 0] or, alternatively, [0 0 1 1 1].

Hamming value (Hv): This is the number of 1's within a tuple. For example [1 0 1 0 1 1] has a Hamming value of 4.

Traditional median: Given an odd number of values the median is the central value of the ordered set. For example given [3 1 2 4 7], they are ordered as [1 2 3 4 7]. The central value, the median, is 3.

Outliers: Given a set of values, the outliers are the extreme values of the ordered set. For example given [27 3 1 2 4 7], they are ordered as [1 2 3 4 7 27]. The outliers are 1 and 27.

Weightless median: Given an odd number of weightless tuples the weightless median is the central tuple of the set ordered by Hamming value. If there is an even number of weightless tuples the weightless median may be taken to be either of the tuples to either side of the non-existent median, and this is still referred to herein as a weightless median. Thus for an even number of weightless tuples the weightless median may not be a unique value. Alternatively, the set may be made up to an odd number by duplication of one of the tuples. The resultant weightless median is likewise also referred to as a weightless median.

Weightless outlier: Given any number of weightless tuples the weightless outliers are the extreme tuples of the set ordered by Hamming value.

For example, given 5 weightless tuples, t1 to t5;

t1=[0 0 1 0 0 0], Hv=1 lowest

t2=[1 0 0 1 0 0], Hv=2

t3=[0 0 1 0 0 0], Hv=1 (equal lowest)

t4=[0 0 1 1 0 1], Hv=3 highest

t5=[1 1 0 0 0 0], Hv=2

Ordering these tuples according to their Hamming value gives;

t4=[0 0 1 1 0 1], Hv=3 Highest outlier

t2=[1 0 0 1 0 0], Hv=2

t5=[1 1 0 0 0 0], Hv=2 Weightless median

t3=[0 0 1 0 0 0], Hv=1

t1=[0 0 1 0 0 0], Hv=1 Lowest outlier

Hence t5, or t2, is the weightless median. The selection of t5 or t2 as the weightless median is unimportant.

### SUMMARY OF THE INVENTION

According to one aspect of this invention there is provided a method of ordering a set of weightless binary input tuples according to their Hamming value which comprises the steps of:

operating in a first stage on a subset of at least two of said tuples, to order said tuples according to which has the greater number of 1's set, and

repeating said operating step in successive stages with respective subsets of said tuples, to provide an output of an ordered set of said tuples in which the original bit pattern thereof is preserved.

In one arrangement, each of said subsets comprises two tuples, and in each stage at least one of the tuples not contained in the subset passes unmodified to a subsequent stage.

Preferably said operating step comprises thermocoding each of the weightless binary input tuples in said subset and determining which of said thermocoded tuples has the greater number of logic 1's, and reversing the order or said weightless binary input tuples if a pre-selected one of said tuples has a higher number of 1's set.

In another aspect, this invention provides apparatus for ordering a set of weightless binary input tuples, which comprises:

a plurality of logic modules, each logic module being operable to receive a subset of at least two tuples and to order said tuples according to which has the greater number of 1's set,

said plurality of logic modules being interconnected successively to operate on respective subsets of at least two tuples,

thereby to provide an output of an ordered set in which the weightless binary input tuples are arranged in order of the number of 1's set, whilst preserving the original bit pattern thereof.

Preferably each module is operable to receive a subset of two tuples, the set of weightless binary input tuples comprises an odd number of tuples (T1-T3), and said logic modules are arranged in stages of one or more logic modules.

Preferably in each stage, at least one tuple passes through to the next stage without being operated on by the logic module or modules in said stage.

Preferably each module comprises:

a first thermocoder for thermocoding one of said tuples;

a second thermocoder for thermocoding the other of said tuples;

a comparator for receiving the thermocoded tuples and determining whether the number of 1's set in the tuple from a pre-determined one of said first and second thermocoders is greater than that in the other tuple thereof, and

a selector circuit for ordering the tuples of said subset in accordance with the output of the comparator.

Preferably at least some of the logic modules are made up by Boolean logic circuit elements, and in certain embodiments, all of said logic modules are made up of Boolean logic circuit elements.

Whilst the invention has been described above, it extends to any inventive combination of the features set out in the following description or claims.

The invention may be performed in various ways, and an embodiment thereof will now be described by way of example only, reference being made to the accompanying drawings, in which:

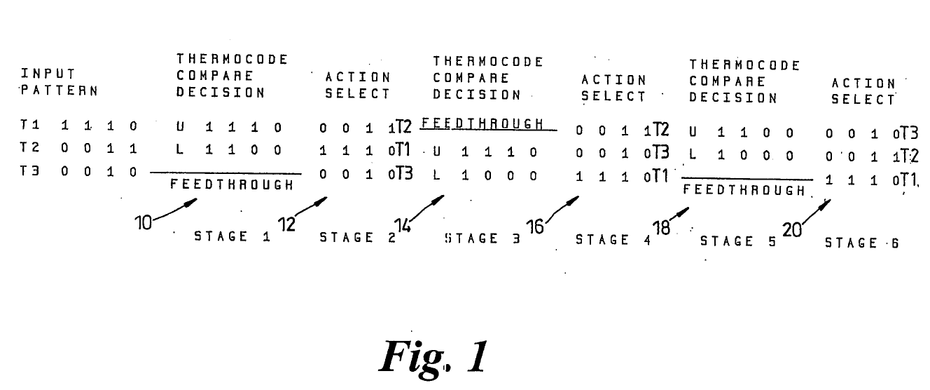

FIG. 1 illustrates schematically the steps involved in the implementation of a device for ordering three input tuples according to their Hamming value;

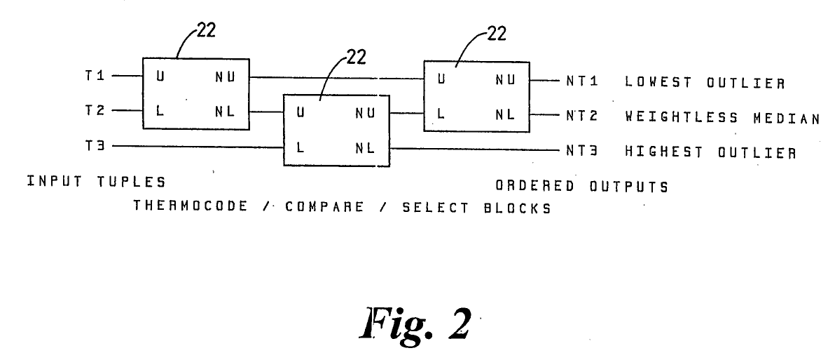

FIG. 2 is a schematic diagram illustrating a modular structure for ordering three input tuples according to their Hamming value;

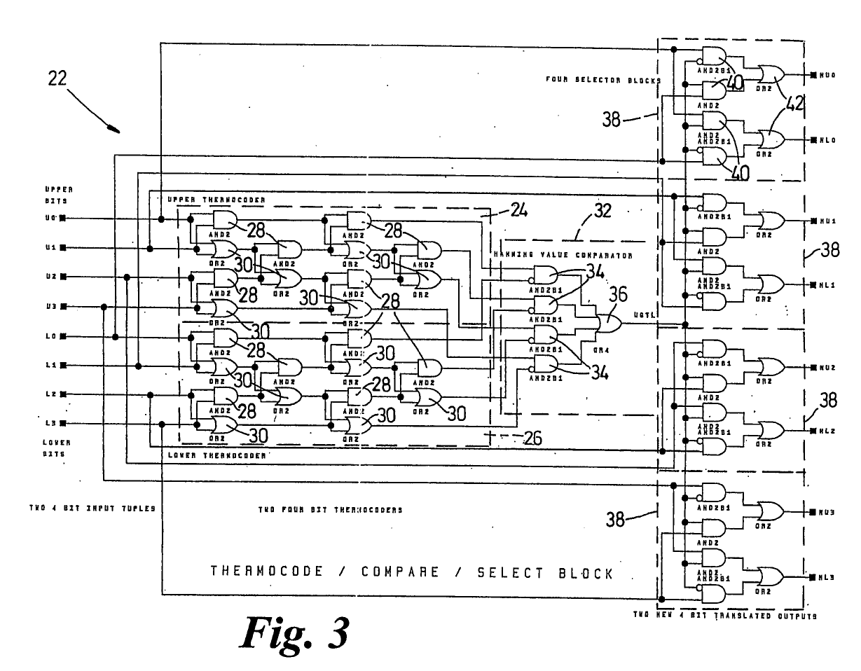

FIG. 3 is a circuit diagram illustrating an embodiment of a Boolean logic implementation of the modules shown in FIG. 2, and

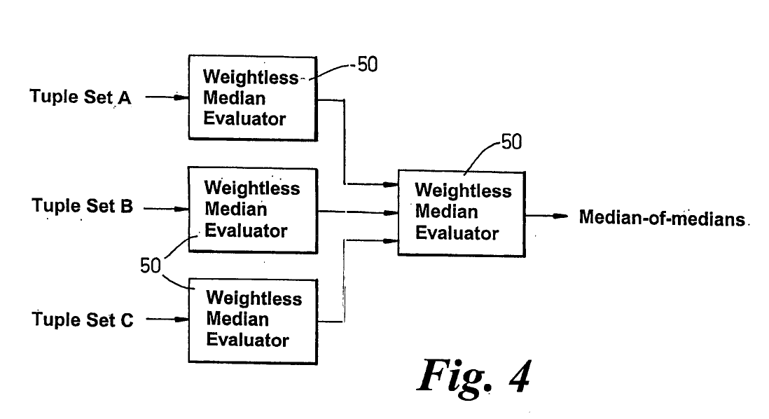

FIG. 4 illustrates an embodiment wherein there is provided a hierarchy of weightless mean evaluators.

Referring initially to FIG. 1, there is shown schematically an example of the steps involved in the implementation of a device for ordering three input tuples (1 1 1 0), (0 0 1 1) and (0 0 1 0) according to their Hamming value (Hv) whilst preserving the original bit pattern order, such that an original set of tuples:

T1 1 1 1 0 Hv=3

T2 0 0 1 1 Hv=2

T3 0 0 1 0 Hv=1

are ordered into the set:

T3 0 0 1 0 Hv=1

T2 0 0 1 1 Hv=2

T1 1 1 1 0 Hv=3

The process in FIG. 1 is described in six stages 10, 12, 14, 16, 18, 20. In the first stage 10, T1 and T2 are thermocoded to the left (left-thermocoded) and compared. A decision is made as to whether the Hamming value of T1 (the upper tuple) is greater than that of T2 (the lower tuple). The third tuple T3 is passed through the first stage unaltered. In this example the Hamming value of the upper tuple (T1) is greater than that of the lower tuple (T2) and this decision is used in the second stage 12 to swap the upper and lower tuples T1 and T2 so that the new upper tuple (NU) is T2, and the new lower tuple (NL) is T1 and the lowermost tuple T3 is a feedthrough direct from the input.

In the third and fourth stages (14, 16) a similar operation to those of the first and second stages is carried out except that in the third stage the uppermost tuple (T2 in this example) feeds through direct to the fourth stage, and the lower two tuples (T1 and T3) are left-thermocoded, compared, and a decision is made as to whether the Hamming value of the upper tuple is greater than that of the lower tuple (here T3). Again in this example the Hamming value of the upper tuple is greater and so this decision is used in the fourth stage 16 to swap the upper and lower tuples so that the new upper (NU) tuple is T3 and the new lower (NL) tuple is T1. The fifth and sixth stages 18, 20 perform the same operations as the first and second stages 10, 12 with the result that, on completion of the sixth stage the upper two tuples T2 and T3 have been swapped and the lowermost tuple T1 has been passed through direct, so that the output set is:

T3 0 0 1 0

T2 0 0 1 1

T1 1 1 1 0,

i.e. the input tuples ordered according to their Hamming value, whilst preserving the original bit pattern. In this example, the stages 10, 14 18 thermocode to the left but this could be to the right; likewise the comparison operation in these stages causes the higher thermocoded tuples to migrate downwards, but this could be upwards.

Although in this embodiment just three input tuples are ordered by Hamming Value, it will of course be immediately apparent that the principle may readily be expanded to allow ordering of a greater number of tuples, by increasing the number of rows and modules accordingly.

It will be noted that the six stages of FIG. 1 may be implemented as a modular structure as shown in FIG. 2. Here each module 22 comprises a thermocode, compare and select block performing the function of e.g. the first and second stages. Thus each module receive an upper tuple (U) and a lower tuple (L), left thermocodes the tuples, compares their Hamming values and swaps the tuples if the upper tuple has a higher Hamming value to cause the tuples with the higher Hamming value to migrate downward, with the output tuples being labelled NU for new upper and NL for new lower respectively. The ordered outputs of the modular structure are labelled generically NT1, NT2 and NT3.

Referring now to FIG. 3, an embodiment of a Boolean logic implementation for each module 22 is shown, in this example for operating on two 4-bit tuples U0, U1, U2, U3) and (L0, L1, L2, L3 respectively. The module 22 of FIG. 3 may be resolved into smaller sub modules, namely an upper thermocoder 24 which converts the upper bits (U0, U1, U2, U3) into thermocode and a lower thermocoder 26 which converts the lower bits (L0 L1 L2 L3) into thermocode. Each thermocoder 24, 26 is of the same structure, made up of an arrangement of AND gates 28 and OR gates 30 in the manner shown in the Figure. This type of thermocoder is described in more detail in our published International Application No. WO 99/33184, the contents of which are incorporated herein by reference. The thermocoded upper and lower bits are then supplied to a Hamming value comparator sub module 32 made up of a set of four two input AND gates 34 with one input of each inverted. The set of AND gates 34 compares the bits at each bit position in the upper and lower tuples and outputs a logic 1 if at any bit position there is a ‘1’ in the upper tuple and a ‘0’ in the lower tuple, thus indicating that the Hamming value of the upper tuple is greater than that of the lower tuple. The outputs from the AND gates 34 are ORed together by an OR gate 36. The output UGTL (with ‘1’ indicating that the Hamming value of the upper tuple is greater than that of the lower tuple) is passed to four selector blocks 38 each of which is made up a four 2-input AND gates 40 with selected inputs inverted as shown and the outputs passing to two OR gates 42 the outputs of which provide new upper and new lower bits NUn and LUn respectively.

Each selector block 38 also receives a bit (Un, Ln) from each of the upper and lower tuples at a respective bit position. Thus the uppermost block receives U0 and L0, the next block receives U1 and L1 and so on. In each case a ‘1’ UGTL output causes the selector block 38 to swap the bits, such that, e.g. the bit U0 appears on the output new L0 (NL0) and the bit L0 appears on the output new U0 (NU0).

Although the implementation of FIG. 3 uses two 4-bit thermocoders comprising 2-bit thermocoder cells, it will be appreciated that other cell sizes could be employed. If required this device could be implemented in an architecture using pipeline registers for certain synchronous applications in a manner similar to that described in relation to FIGS. 2 and 3 of WO 99/33184.

It will be appreciated that the device of for example FIG. 2 may be used to determine a weightless median of the input tuples T1, T2, T3 simply by selecting the centre output tuple NT2.

Furthermore it should be noted that in this embodiment hierarchies of median evaluators may be formed as shown in FIG. 4. Here is shown a hierarchy in which a first layer of weightless median evaluators 50 evaluate the respective medians for Tuple sets A, B and C, the outputs of which pass to a second layer, which in this instance comprises a single weightless median evaluator 50 to provide as an output a median-of-medians. Tuple sets A B and C may comprise different numbers of tuples but the tuple bit width should normally be the same. In certain situations the tuples may be padded with 0's or 1's, but in others padding with 0's or 1's may introduce a bias which may be undesirable.

The weightless median or median-of-medians may be used as a generic template in devices such as the neuroram and related systems described in our published International Application No. WO 99/33019.

In other applications the weightless median or median-of-medians may be used to identify “cluster centres” e.g. in sensor data fusion applications. Thus in sensor data fusion, cluster centres can be identified from multiple (e.g. airborne) data sources, often with dissimilar characteristics, e.g. RADAR, LIDAR (light detection and ranging), infra-red, and visible light-sensors.

It will readily be appreciated that, being logic based, the embodiments herein are not restricted to any particular type of technological implementation, and so they mat be implemented e.g. using optical, magnetic, electromagnetic, electronic, or ionic technologies, or combinations thereof.

1. A method of ordering a set of weightless binary input tuples according to their Hamming value which comprises the steps of:
operating in a first stage on a subset of at least two of said tuples, to order said tuples according to which has the greater number of 1's set, and
repeating said operating step in successive stages with respective subsets of said tuples, to provide an output of an ordered set of said tuples in which the original bit pattern thereof is preserved.

2. A method according to Claim 1, wherein each of said subsets comprises two tuples.

3. A method according to Claim 1 or Claim 2, wherein in each stage at least one of the tuples not contained in the subset passes unmodified to a subsequent stage.

4. A method according to Claim 2 or Claim 3, wherein each said operating step comprises thermocoding each of the weightless binary input tuples in said subset and determining which of said thermocoded tuples has the greater number of logic 1's, and reversing the order or said weightless binary input tuples if a pre-selected one of said tuples has a higher number of 1's set.

5. Apparatus for ordering a set of weightless binary input tuples, which comprises:
a plurality of logic modules (22), each logic module being operable to receive a subset of at least two tuples and to order said tuples according to which has the greater number of 1's set,
said plurality of logic modules (22) being interconnected successively to operate on respective subsets of at least two tuples,
thereby to provide an output of an ordered set in which the weightless binary input tuples are arranged in order of the number of 1's set, whilst preserving the original bit pattern thereof.

6. Apparatus according to Claim 5, wherein each module (22) is operable to receive a subset of two tuples.

7. Apparatus according to Claim 6, wherein the set of weightless binary input tuples comprises an odd number of tuples (T1-T3) and said logic modules (22) are arranged in stages of one or more logic modules.

8. Apparatus according to Claim 7, wherein in each stage, at least one tuple passes through to the next stage without being operated on by the logic module or modules in said stage.

9. Apparatus according to Claim 6 or any claim dependent thereon wherein each module comprises:
a first thermocoder (24) for thermocoding one of said tuples;
a second thermocoder (26) for thermocoding the other of said tuples;
a comparator (32) for receiving the thermocoded tuples and determining whether the number of 1's set in the tuple from a pre-determined one of said first and second thermocoders is greater than that in the other tuple thereof, and
a selector circuit 38 for ordering the tuples of said subset in accordance with the output of the comparator (32).

10. Apparatus according to any of claims 6 to 9 wherein at least some of the logic modules (22) are made up by Boolean logic circuit elements.

11. Apparatus according to Claim 10, wherein all of said logic modules (22) are made up of Boolean logic circuit elements.
